(19) United States
(12) Patent Application Publication
(10) Pub. No.: US 2011/0097901 A1
(43) Pub. Date: Apr. 28, 2011

(54) DUAL MODE INDUCTIVELY COUPLED PLASMA REACTOR WITH ADJUSTABLE PHASE COIL ASSEMBLY

(75) Inventors: SAMER BANNA, San Jose, CA (US); VALENTIN N. TODOROW, Palo Alto, CA (US); KENNETH S. COLLINS, San Jose, CA (US); ANDREW NGUYEN, San Jose, CA (US); MARTIN JEFF SALINAS, San Jose, CA (US); ZHIGANG CHEN, San Jose, CA (US); ANKUR AGARWAL, Mountain View, CA (US); ANNIRUDDHA PAL, Santa Clara, CA (US); TSE-CHIANG WANG, Concord, CA (US); SHAHID RAUF, Pleasanton, CA (US)

(73) Assignee: APPLIED MATERIALS, INC., Santa Clara, CA (US)

(21) Appl. No.: 12/821,636

(22) Filed: Jun. 23, 2010

Related U.S. Application Data
(60) Provisional application No. 61/254,837, filed on Oct. 26, 2009.

(51) Int. Cl. H01L 21/465; H01L 21/46

(52) U.S. Cl. 438/710; 156/345.48; 156/345.37; 118/723 I; 438/758; 257/E21.482; 257/E21.485

(57) ABSTRACT

Embodiments of dual mode inductively coupled plasma reactors and methods of use of same are provided herein. In some embodiments, a dual mode inductively coupled plasma processing system may include a process chamber having a dielectric lid and a plasma source assembly disposed above the dielectric lid. The plasma source assembly includes a plurality of coils configured to inductively couple RF energy into the process chamber to form and maintain a plasma therein, a phase controller for adjusting the relative phase of the RF current applied to each coil in the plurality of coils, and an RF generator coupled to the phase controller and the plurality of coils.

### CROSS-REFERENCE TO RELATED APPLICATIONS

This application claims benefit of U.S. provisional patent application Ser. No. 61/254,837, filed Oct. 26, 2009, which is herein incorporated by reference in its entirety.

### BACKGROUND

1. Field

Embodiments of the present invention generally relate to semiconductor processing equipment, and, more specifically, to inductively coupled plasma processing systems.

2. Description

Inductively coupled plasma (ICP) process reactors generally form plasmas by inducing current in a process gas disposed within the process chamber via one or more inductive coils disposed outside of the process chamber. The inductive coils may be disposed externally and separated electrically from the chamber by, for example, a dielectric lid. For some plasma processes, a heater element may be disposed above the dielectric lid to facilitate maintaining a constant temperature of the dielectric lid during and between processes.

The coils, for example, two, are coaxially arranged to form an inner coil and an outer coil. Each of the coils is wound in the same direction—counterclockwise or clockwise. Both coils are driven with a common radio frequency (RF) source. Typically, an RF matching circuit couples the RF power from the RF source to an RF splitter. The RF power is simultaneously applied to both the inner and outer coils.

Under certain process conditions, such ICP process reactors may produce an M-shaped etch rate, where the center and edges of a wafer etch more slowly than an annular, central portion of the wafer. For some processes, such an etch rate profile is of no significant consequence. However, in, for example, shallow trench isolation (STI) processes, depth uniformity is important. As such, an M-shaped etch rate profile can be detrimental to accurate integrated circuit creation. Moreover, as the technology is moving towards finer features, etch rate uniformity across the substrate is becoming more vital. M-shape, among other non-uniform processing results, limits such fine control, and therefore, degrading the overall electrical performance of the device.

Thus, the inventors have provided an inductively coupled plasma reactor having improved etch rate uniformity via enhanced RF control of ICP sources.

### SUMMARY

Embodiments of dual mode inductively coupled plasma reactors and methods of use of same are provided herein. In some embodiments, a dual mode inductively coupled plasma processing system may include a process chamber having a dielectric lid and a plasma source assembly disposed above the dielectric lid. The plasma source assembly includes a plurality of coils configured to inductively couple RF energy into the process chamber to form and maintain a plasma therein. The plasma source assembly further comprises a phase controller for controlling the relative phase of the RF current applied to each coil.

In some embodiments, a dual mode inductively coupled plasma processing system may include a process chamber having a dielectric lid; an annular heater positioned proximate the dielectric lid; a plasma source assembly disposed above the dielectric lid, the plasma source assembly including: a first coil being wound in a first direction and a second coil being wound in a second direction, the first and second coils configured to inductively couple RF energy into the process chamber to form and maintain a plasma therein; a phase controller coupled to the first and second coils for controlling the relative phase of RF current applied to each coil; one or more electrodes configured to capacitively couple RF energy into the process chamber to form the plasma therein, wherein the one or more electrodes are electrically coupled to one of the one or more coils; and an RF generator coupled to the phase controller and each of the coils through a central feed. In some embodiments, the first direction and second direction are opposite one another.

In some embodiments, a method of forming a plasma may include providing a process gas to an inner volume of a process chamber having a dielectric lid and having a plurality of coils disposed above the lid. RF power is provided to the one or more coils from an RF power source. A plasma is formed from the process gas using the RF power provided by the RF power source that is inductively coupled to the process gas by the one or more coils. A phase controller controls the relative phase of the RF current applied to each coil.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of a dual mode inductively coupled plasma reactor in accordance with some embodiments of the present invention.

FIG. 2 depicts a schematic diagram of a power source assembly in accordance with some embodiments of the present invention.

FIGS. 3A-B depicts a partial schematic side view of a dual mode inductively coupled plasma reactor in accordance with some embodiments of the present invention.

FIGS. 4A-B depict an RF feed structure in accordance with some embodiments of the present invention.

FIGS. 5A-B depict schematic top views of an inductively coupled plasma apparatus in accordance with some embodiments of the present invention.

FIG. 6 depicts a flow chart for a method of forming a plasma in accordance with some embodiments of the invention.

FIG. 7 depicts an illustration of respective etch rate profiles using in-phase power and an etch rate profile using out-of-phase power.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of dual mode inductively coupled plasma reactors and methods of use of same are provided herein. The inventive inductively coupled plasma reactors may advantageously provide improved and/or controlled plasma processing (such as, for example etch uniformity) through controlling the relative phase of radio frequency (RF) current applied to respective coils of the reactor. Moreover, the inventive inductively coupled plasma reactors provided herein may advantageously operate in a standard mode in which the currents in both coils are in phase, and in a phase control mode, where the phase of the RF current flowing in a pair of inductive RF coils may be controlled, for example, such that the RF currents in both coils may be switched from in-phase to out-of-phase. Such dual mode operation may be advantageous for customers who need the improved performance for some processes, but who also perform other processes that they do not wish to run on new equipment that has not been qualified to run that process, and where they already achieve acceptable performance with the standard mode of operation.

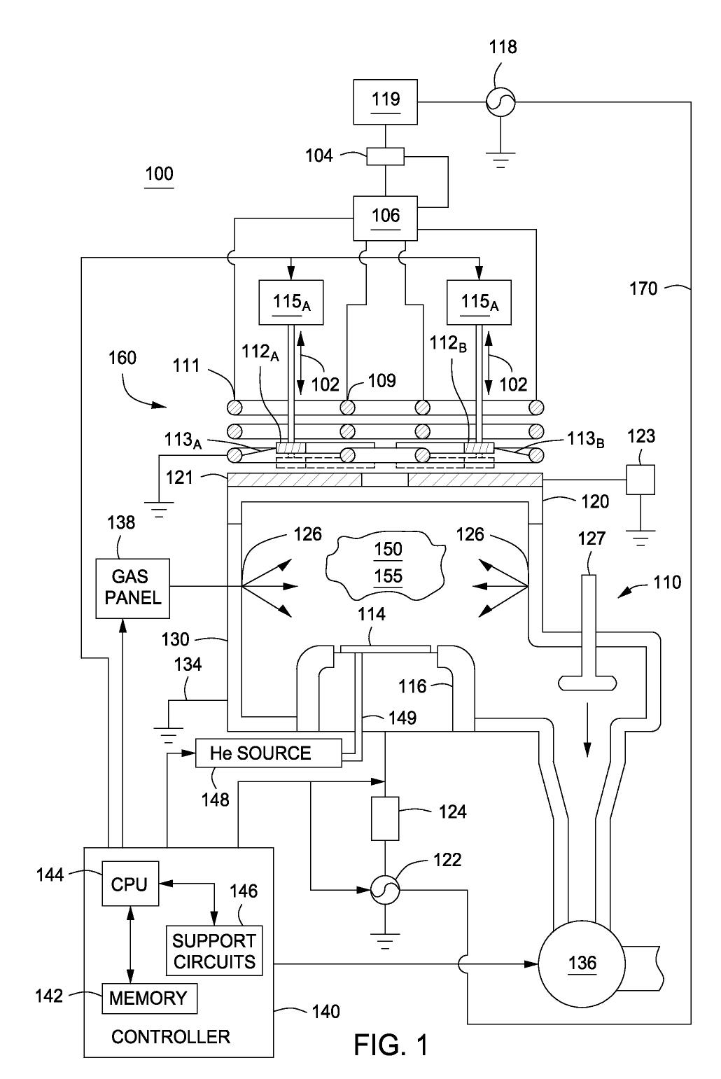

FIG. 1 depicts a schematic side view of a dual mode inductively coupled plasma reactor (reactor 100) in accordance with some embodiments of the present invention. The reactor 100 may be utilized alone or, as a processing module of an integrated semiconductor substrate processing system, or cluster tool, such as a CENTURA® integrated semiconductor wafer processing system, available from Applied Materials, Inc. of Santa Clara, Calif. Examples of suitable plasma reactors that may advantageously benefit from modification in accordance with embodiments of the present invention include inductively coupled plasma etch reactors such as the DPS® line of semiconductor equipment (such as the DPS®, DPS® II, DPS® AE, DPS® G3 poly etcher, DPS® G5, or the like) also available from Applied Materials, Inc. The above listing of semiconductor equipment is illustrative only, and other etch reactors, and non-etch equipment (such as CVD reactors, or other semiconductor processing equipment) may also be suitably modified in accordance with the present teachings.

The plasma reactor includes a plasma source assembly 160 disposed atop a process chamber 110. The assembly 160 comprises a matching network 119, a phase controller 104 and a plurality of coils, for example, a first, or inner RF coil 109 and a second, or outer RF coil 111. The assembly 160 may further include an RF feed structure 106 for coupling an RF power supply 118 to a plurality of RF coils, e.g., the first and second RF coils 109, 111. In some embodiments, the plurality of RF coils are coaxially disposed proximate the process chamber 110 (for example, above the process chamber) and are configured to inductively couple RF power into the process chamber 110 to form a plasma from process gases provided within the process chamber 110.

The RF power supply 118 is coupled to the RF feed structure 106 via a match network 119. The phase controller 104 may be provided to adjust the RF power respectively delivered to the first and second RF coils 109, 111. The phase controller 104 may be coupled between the match network 119 and the RF feed structure 106. Alternatively, the phase controller may be a part of the match network 119, in which case the match network will have two outputs coupled to the RF feed structure 106—one corresponding to each RF coil 109, 111.

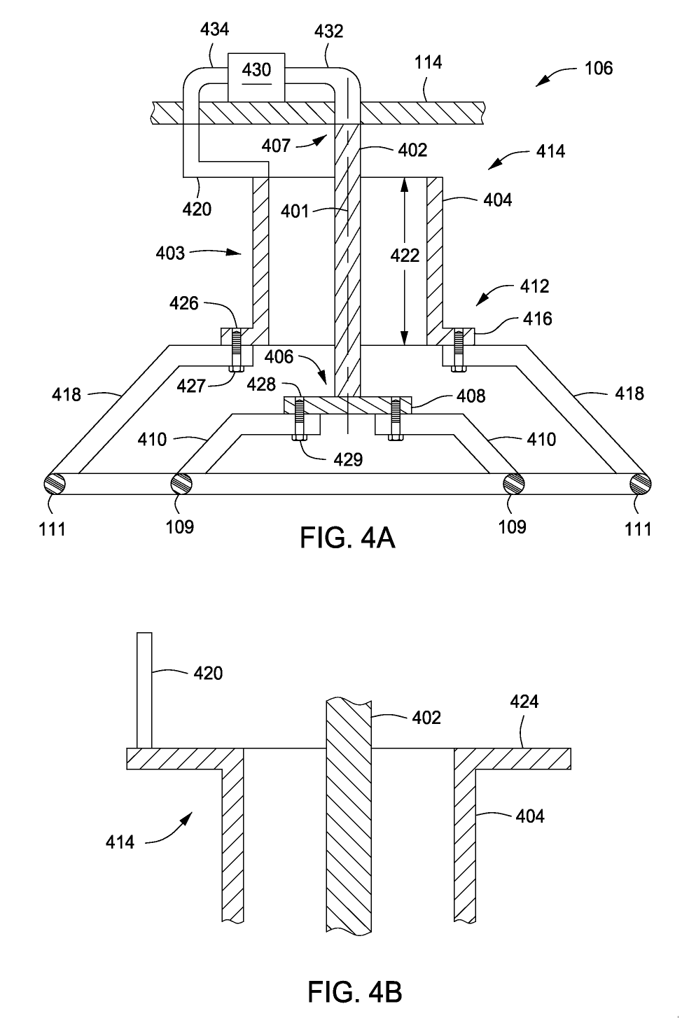

The RF feed structure 106 couples the RF current from the phase controller 104 (or the match network 119 where the phase controller is incorporated therein) to the respective RF coils. In some embodiments, the RF feed structure 106 may be configured to provide the RF current to the RF coils in a symmetric manner, such that the RF current is coupled to each coil in a geometrically symmetric configuration with respect to a central axis of the RF coils. Some embodiments of the RF feed structure is described in more detail below with respect to FIGS. 4A-B.

The reactor 100 generally includes a process chamber 110 having a conductive body (wall) 130 and a dielectric lid 120 (that together define a processing volume), a substrate support pedestal 116 disposed within the processing volume, a plasma source assembly 160, and a controller 140. The wall 130 is typically coupled to an electrical ground 134. In some embodiments, the support pedestal (cathode) 116 may be coupled, through a first matching network 124, to a biasing power source 122. The biasing source 122 may illustratively be a source of up to 1000 W at a frequency of approximately 13.56 MHz that is capable of producing either continuous or pulsed power, although other frequencies and powers may be provided as desired for particular applications. In other embodiments, the source 122 may be a DC or pulsed DC source.

In some embodiments, a link 170 may be provided to couple the RF power supply 118 and the biasing source 122 to facilitate synchronizing the operation of one source to the other. Either RF source may be the lead, or master, RF generator, while the other generator follows, or is the slave. The link 170 may further facilitate operating the RF power supply 118 and the biasing source 122 in perfect synchronization, or in a desired offset, or phase difference. The phase control may be provided by circuitry disposed within either or both of the RF source or within the link 170 between the RF sources. This phase control between the source and bias RF generators (e.g., 118, 122) may be provided and controlled independent of the phase control over the RF current flowing in the plurality of RF coils coupled to the RF power supply 118. Further details regarding phase control between the source and bias RF generators may be found in commonly owned, U.S. patent application Ser. No. 12/465,319, filed May 13, 2009 by S. Banna, et al., and entitled, “METHOD AND APPARATUS FOR PULSED PLASMA PROCESSING USING A TIME RESOLVED TUNING SCHEME FOR RF POWER DELIVERY,” which is hereby incorporated by reference in its entirety.

In some embodiments, the dielectric lid 120 may be substantially flat. Other modifications of the chamber 110 may have other types of lids such as, for example, a dome-shaped lid or other shapes. The plasma source assembly 160 is typically disposed above the lid 120 and is configured to inductively coupling RF power into the process chamber 110. The plasma source assembly 160 includes a plurality of inductive coils and a plasma power source. In some embodiments, one or more electrodes 112_{A} and 112_{B} may also be coupled to one or more of the plurality of coils, as described in more detail below. The plurality of inductive coils may be disposed above the dielectric lid 120. As shown in FIG. 1, two coils are illustratively shown (an inner coil 109 and an outer coil 111) disposed above the lid 120. The coils may be concentrically arranged, for example, having the inner coil 109 disposed within the outer coil 111. The relative position, ratio of diameters of each coil, and/or the number of turns in each coil can each be adjusted as desired to control, for example, the profile or density of the plasma being formed. Each coil of the plurality of inductive coils (e.g., coils 109, 111 as shown in FIG. 1) is coupled, through a second matching network 119, to a plasma power source 118. The plasma source 118 may illustratively be capable of producing up to 4000 W at a tunable frequency in a range from 50 kHz to 13.56 MHz, although other frequencies and powers may be provided as desired for particular applications.

In some embodiments, the phase controller 104 divides the RF power applied to the coils 109 and 111 to control the relative quantity of RF power provided by the plasma power source 118 to the respective coils and control the relative phase of the applied current. For example, as shown in FIG. 1, the phase controller 104 is disposed in the line coupling the inner coil 109 and the outer coil 111 to the plasma power source 118 for controlling the amount and phase of RF power provided to each coil (thereby facilitating control of plasma characteristics in zones corresponding to the inner and outer coils as well as control of etch rate uniformity). To maximize the amount of power coupled to the plasma, a matching network 119 is disposed between the RF source 118 and the phase controller 104.

The one or more optional electrodes are electrically coupled to one of the plurality of inductive coils (e.g., as depicted in FIG. 1, either the inner coil 109 or the outer coil 111). In one exemplary non-limiting embodiment, and as illustrated in FIG. 1, the one or more electrodes of the plasma source assembly 160 may be two electrodes 112_{A}, 112_{B} disposed between the inner coil 109 and the outer coil 111 and proximate the dielectric lid 120. Each electrode 112_{A}, 112_{B} may be electrically coupled to either the inner coil 109 or the outer coil 111. As depicted in FIG. 1, each electrode 112_{A}, 112_{B} is coupled to the outer coil 111 via respective electrical connectors 113_{A}, 113_{B}. RF power may be provided to the one or more electrodes via the plasma power source 118 via the inductive coil to which they are coupled (e.g., the inner coil 109 or the outer coil 111 in FIG. 1). A description of the use of such electrodes is contained in commonly assigned U.S. patent application Ser. No. 12/182,342, filed Jul. 30, 2008 by V. Todorow, et al., and entitled, “Field Enhanced Inductively Coupled Plasma (FE-ICP) Reactor.

In some embodiments, and as depicted in FIG. 1, positioning mechanisms 115_{A}, 115_{B} may be coupled to each of the electrodes (e.g., electrodes 112_{A}, 112_{B}) to independently control the position and orientation thereof (as indicated by vertical arrows 102 and the phantom extension of the electrodes 112_{A}, 112_{B}). In some embodiments, the positioning mechanism(s) may independently control the vertical position of each electrode of the one or more electrodes. For example, as depicted in FIG. 4A, the position of electrode 112_{A} may be controlled by positioning mechanism 115_{A} independently of the position of electrode 112_{B}, as controlled by positioning mechanism 115_{B}. In addition, the positioning mechanisms 115_{A}, 115_{B} may further control the angle, or tilt of the electrodes (or an electrode plane defined by the one or more electrodes).

A heater element 121 may be disposed atop the dielectric lid 120 to facilitate heating the interior of the process chamber 110. The heater element 121 may be disposed between the dielectric lid 120 and the inductive coils 109, 111 and electrodes 112_{A-B}. In some embodiments, the heater element 121 may include a resistive heating element and may be coupled to a power supply 123, such as an AC power supply, configured to provide sufficient energy to control the temperature of the heater element 121 to be between about 50 to about 100 degrees Celsius. In some embodiments, the heater element 121 may be an open break heater. In some embodiments, the heater element 121 may comprise a no break heater, such as an annular element, thereby facilitating uniform plasma formation within the process chamber 110.

During operation, a substrate 114 (such as a semiconductor wafer or other substrate suitable for plasma processing) may be placed on the pedestal 116 and process gases may be supplied from a gas panel 138 through entry ports 126 to form a gaseous mixture 150 within the process chamber 110. The gaseous mixture 150 may be ignited into a plasma 155 in the process chamber 110 by applying power from the plasma source 118 to the inductive coils 109, 111 and, if used, the one or more electrodes (e.g., 112_{A} and 112_{B}). The phase controller 104 is instructed by the controller 140 to adjust the relative phase of the RF power to each coil, thus, controlling the etch rate profile. In some embodiments, power from the bias source 122 may be also provided to the pedestal 116. The pressure within the interior of the chamber 110 may be controlled using a throttle valve 127 and a vacuum pump 136. The temperature of the chamber wall 130 may be controlled using liquid-containing conduits (not shown) that run through the wall 130.

The temperature of the wafer 114 may be controlled by stabilizing a temperature of the support pedestal 116. In one embodiment, helium gas from a gas source 148 may be provided via a gas conduit 149 to channels defined between the backside of the wafer 114 and grooves (not shown) disposed in the pedestal surface. The helium gas is used to facilitate heat transfer between the pedestal 116 and the wafer 114. During processing, the pedestal 116 may be heated by a resistive heater (not shown) within the pedestal to a steady state temperature and the helium gas may facilitate uniform heating of the wafer 114. Using such thermal control, the wafer 114 may illustratively be maintained at a temperature of between 0 and 500 degrees Celsius.

The controller 140 comprises a central processing unit (CPU) 144, a memory 142, and support circuits 146 for the CPU 144 and facilitates control of the components of the reactor 100 and, as such, of methods of forming a plasma, such as discussed herein. The controller 140 may be one of any form of general-purpose computer processor that can be used in an industrial setting for controlling various chambers and sub-processors. The memory, or computer-readable medium, 142 of the CPU 144 may be one or more of readily available memory such as random access memory (RAM), read only memory (ROM), floppy disk, hard disk, or any other form of digital storage, local or remote. The support circuits 146 are coupled to the CPU 144 for supporting the processor in a conventional manner. These circuits include cache, power supplies, clock circuits, input/output circuitry and subsystems, and the like. The inventive method may be stored in the memory 142 as software routine that may be executed or invoked to control the operation of the reactor 100 in the manner described above. In particular, the controller 140 controls the phase controller to adjust the relative phase of RF power coupled to the coils 109, 111. The software routine may also be stored and/or executed by a second CPU (not shown) that is remotely located from the hardware being controlled by the CPU 144.

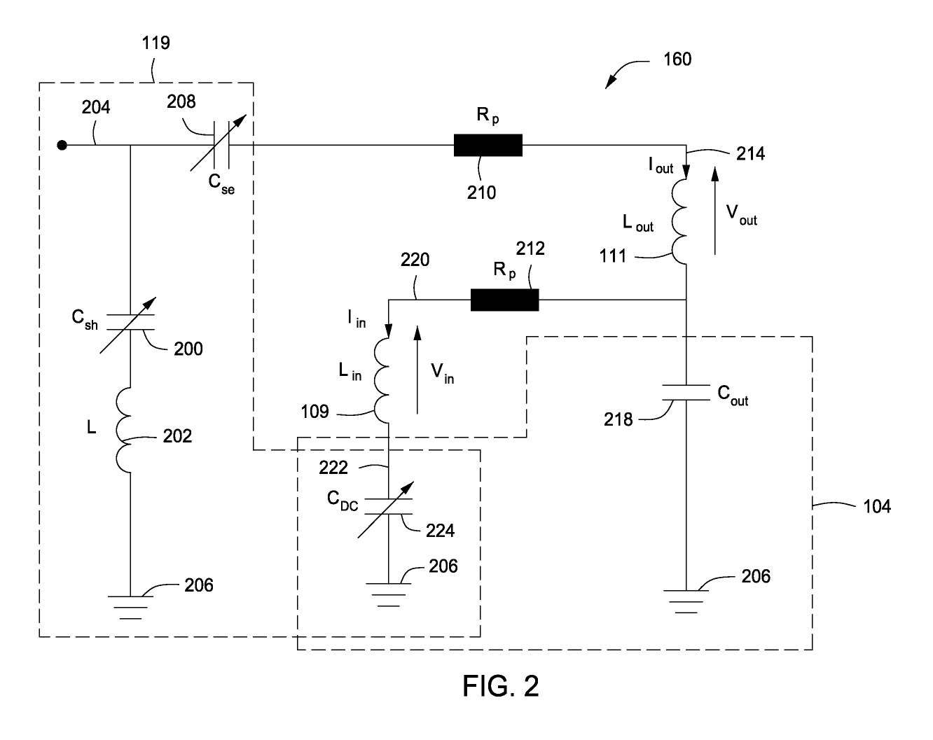

FIG. 2 depicts a schematic diagram of the plasma source assembly 160 in accordance with some embodiments of the present invention. The assembly 160 comprises the matching network 119, the phase controller 104 and a plurality of coils, for example, the coils 109, 111. The matching network 119 may be a conventional network comprising, in sine embodiments, variable capacitor 200 (shunt capacitor) coupled in series to a fixed inductor 202. The capacitor 200 and inductor 202 are coupled from the input 204 to ground 206. A series connected variable capacitor 208 (series capacitor) connects the input to the output of the matching network 119. The capacitors 200, 208 and inductor 202 form a L-network form of matching network 110. Other embodiments may use fixed capacitors and/or variable inductors in L-, π or other forms of networks.

The output of the matching network 119 is coupled to the coils 109 and 111 and the phase controller 104. The resistive component of the circuitry is represented by elements 210, 212. In some embodiments of the invention, the outer coil 111 and inner coil 109 are connected in series. A first terminal 214 of outer coil 111 is coupled to the matching network 119. A second terminal 216 is coupled to a capacitor 218 to ground 206 and first terminal 220 of the inner coil 109. A second terminal 222 of inner coil 109 is coupled through a variable capacitor 224 to ground 206. The variable capacitor 224 may be a dividing capacitor that controls the current ratio of the RF current flowing through each of the inner and outer coils 109, 111. The capacitors 218 and 224 form the phase controller 104 that controls the relative phase of the RF current flowing through each coil 109, 111. In some embodiments, the capacitor 218 may have a fixed value and the capacitor 224 may be variable. For example, in some embodiments, the capacitor 218 may have a fixed value between about 100 pF and about 2000 pF, and capacitor 224 may have a value that ranges anywhere from between about 100 pF to about 2000 pF. In some embodiments, both capacitors 218 and 224 are variable.

In some embodiments, when the outer coil 111 and the inner coil 109 are connected in series, the connectors between the coils can serve as capacitive RF electrodes that can enhance the plasma striking capability of the reactor (e.g., the connection between the coils may be the electrodes 112, discussed above).

In the embodiment of FIG. 2, adjusting the capacitor 224 alters the relative phase of the RF current in each coil. Capacitor 218 establishes a set point for in-phase operation, then adjusting the capacitor 224 alters the relative phase to achieve out-of-phase current application to each coil. By varying the phase of the current, the interference between magnetic fields produced by the coils is altered. The interference can be constructive or destructive depending on the relative current phase. The interference can be tuned to achieve specific process results. There is a range of capacitance values of capacitor 224 or 218 that might cause resonance or near resonance of the coil assembly 160 or the overall electrical circuit of the source assembly. Operating close to this resonance might create high voltages on the capacitors and or coils and hence operation at that range should be limited or avoided. Consequently, the capacitance is typically chosen to cause in-phase current application or 180° out-of-phase current application to achieve specific process results, such as reducing the M-shape pattern in etch rate and controlling depth uniformity and cell micro-loading for shallow trench isolation (STI) applications.

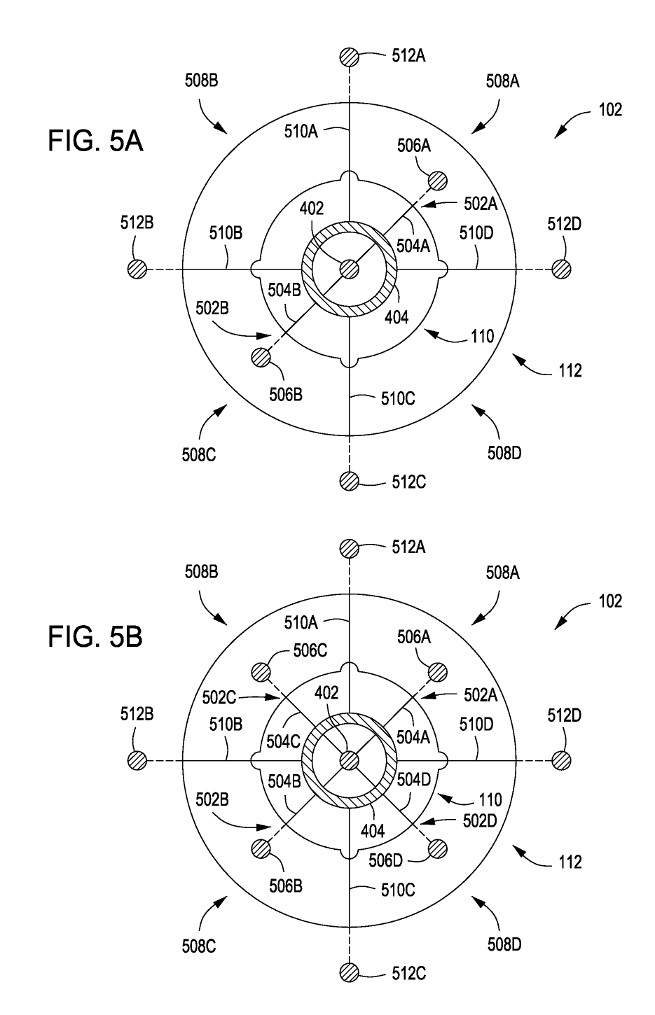

In some embodiments of the invention, the coils 109, 111 may be wound in opposite directions (e.g., respectively clockwise and counter-clockwise). In one exemplary embodiment, the inner coil has 2 or 4 or 8 or 16 turns and a diameter of about five inches, while the outer coil has 2 or 4 or 8 or 16 turns and a diameter of about 15 inches. The number of turns and the coil diameter dictate the inductance of the coil and may be selected as desired. In addition, each of the coils may be comprised of multiple legs, e.g., multiple parallel connected coils coupled to a common feed, where each leg is coupled to ground, or to a capacitor to ground (see, for example, discussion below with respect to FIGS. 5A-B). The number of legs may be chosen to achieve a desirable inductance while maintaining a geometrical symmetry of design. In some embodiments, the common feed may be a central feed (see, for example, discussion below with respect to FIGS. 4A-B). Such a centrally fed coil assembly may be found in U.S. Patent Application Ser. No. 61/254,838, filed on Oct. 26, 2009, by Z. Chen, et al., and entitled “RF FEED STRUCTURE FOR PLASMA PROCESSING,” and U.S. Patent Application Ser. No. 61/254,833, filed on Oct. 26, 2009, by V. N. Todorow, et al., and entitled “INDUCTIVELY COUPLED PLASMA APPARATUS WITH PHASE CONTROL,” each of which are hereby incorporated by reference in their entireties.

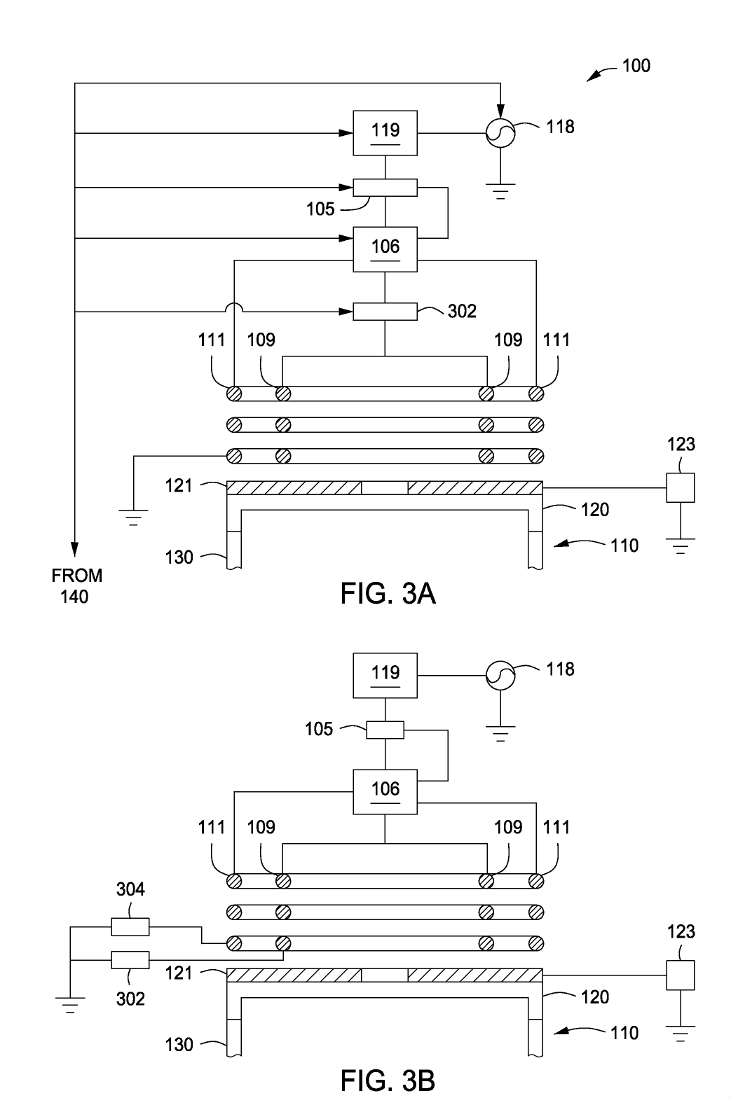

In some embodiments, the phase of an RF signal provided by the RF power supply 118 to each of the first or second RF coils can be controlled using a phase shifting device coupled to the coils. In some embodiments, a phase controller 302 can be coupled to either the first or the second RF coil for shifting the phase of the RF current flowing through the particular RF coil. For example, in some embodiments, the phase controller 302 may be a time delay circuit, for example, based upon capacitors and inductors, suitable for controllably delaying the RF signal going to one of the RF coils. In some embodiments, as illustrated in FIG. 3A, the phase controller 302 may be disposed between the RF feed structure 106 and the first coil 109 for shifting the phase of RF current flowing through the first coil 109. However, the illustration of the phase controller 302 is merely exemplary and the phase controller can be coupled to the second RF coil 111 instead of the first RF coil 109.

In operation, an RF signal is generated by the RF power supply 118. The RF signal travels through the match network 119 (and, in some embodiments, a power divider 105 that controls the ratio of RF current fed to each of the plurality of RF coils), where the signal is split and fed to each of the RF coils. In some embodiments, the power divider may be a dividing capacitor. In some embodiments, the RF signal may enter the second RF coil 111 without further modification. However, the RF signal coupled to the first RF coil 109 first enters the phase controller 302 where the phase of the RF signal may be controlled prior to entering the first RF coil 109. Accordingly, the phase controller 302 allows control of the relative phase of the RF current flowing through the first RF coil 109 with respect to the second RF coil 111 by any amount between 0 and 360 degrees. Thus, the quantity of constructive or destructive interference of the electric field of the plasma may be controlled. When the phase is controlled to be in phase (or zero degrees out of phase), the apparatus may be operable in a standard mode. In some embodiments, the RF current flowing through the first RF coil 109 may be 180 out of phase with the RF current flowing through the second RF coil 111.

In some embodiments, for example, as shown in FIG. 3B, either or both of the RF coils may further have a blocking capacitor disposed between the respective coil and ground. For example, in FIG. 3B, a blocking capacitor 302 is shown coupled between the first RF coil 109 and ground and a blocking capacitor 304 is shown coupled between the second RF coil 111 and ground. Alternatively, a blocking capacitor may be coupled to just one of the RF coils. In embodiments where each coil comprises a plurality of conductive elements (as discussed in more detail below with respect to FIGS. 5A-B), a blocking capacitor may be provided between each conductive element and ground. The blocking capacitors may have a fixed value or may be variable. If variable, the blocking capacitors may further be adjustable manually or via a controller (such as the controller 140). Control over the value of the blocking capacitor(s) coupled to a single RF coil, or control over the respective values of the blocking capacitor(s) coupled to both RF coils facilitates control over the phase of the RF current flowing through the RF coils.

FIGS. 4A-B depict embodiments of an exemplary RF feed structure 106. Further details regarding the exemplary RF feed structure may be found in previously incorporated U.S. Patent Application Ser. No. 61/254,838. For example, FIGS. 4A-B depict the RF feed structure 106 in accordance with some embodiments of the present invention. As depicted in FIG. 4A, the RF feed structure 106 may include a first RF feed 402 and a second RF feed 404 coaxially disposed with respect to the first RF feed 402. The first RF feed 402 is electrically insulated from the second RF feed 404. In some embodiments, the RF feed structure 106 may be substantially linear, having a central axis 401. As used herein, substantially linear refers to the geometry along the axial length of the RF feed structure and excludes any flanges or other features that may be formed near the ends of the RF feed structure elements, for example, to facilitate coupling to either the output of the match network or phase controller or to the input of the RF coils. In some embodiments, and as illustrated, the first and second RF feeds 402, 404 may be substantially linear, with the second RF feed 404 coaxially disposed about the first RF feed 402. The first and second RF feeds 402, 404 may be formed of any suitable conducting material for coupling RF power to RF coils. Exemplary conducting materials may include copper, aluminum, alloys thereof, or the like. The first and second RF feeds 402, 404 may be electrically insulated by one or more insulating materials, such as air, a fluoropolymer (such as Teflon®), polyethylene, or the like.

The first RF feed 402 and the second RF feed 404 are each coupled to different ones of the first or second RF coils 109, 111. In some embodiments, the first RF feed 402 may be coupled to the first RF coil 109. The first RF feed 402 may include one or more of a conductive wire, cable, bar, tube, or other suitable conductive element for coupling RF power. In some embodiments, the cross section of the first RF feed 402 may be substantially circular. The first RF feed 402 may include a first end 406 and a second end 407. The second end 407 may be coupled to an output of the match network 119 (as shown), to a power divider (as shown in FIG. 3), or to a phase controller (as shown in FIG. 1). For example, as depicted in FIG. 4A, the match network 119 may include a power divider 430 having two outputs 432, 434, with the second end 407 of the first RF feed 402 coupled to one of the two outputs (e.g., 432).

The first end 406 of the first RF feed 402 may be coupled to the first coil 109. The first end 406 of the first RF feed 402 may be coupled to the first coil 109 directly, or via some intervening supporting structure (a base 408 is shown in FIG. 4A). The base 408 may be a circular or other shape and may include symmetrically arranged coupling points for coupling the first coil 109 thereto. For example, in FIG. 4A, two terminals 428 are shown disposed on opposite sides of the base 408 for coupling to two portions of the first RF coil via, for example, screws 429 (although any suitable coupling may be provided, such as clamps, welding, or the like).

In some embodiments, and as discussed further below in relation to FIGS. 5A-B, the first RF coil 109 (and/or the second RF coil 111) may comprise a plurality of interlineated and symmetrically arranged stacked coils (e.g., two or more). For example, the first RF coil 109 may comprise a plurality of conductors that are wound into a coil, with each conductor occupying the same cylindrical plane. Each interlineated, stacked coil may further have a leg 410 extending inwardly therefrom towards a central axis of the coil. In some embodiments, each leg extends radially inward from the coil towards the central axis of the coil. Each leg 410 may be symmetrically arranged about the base 408 and/or the first RF feed 402 with respect to each other (for example two legs 180 degrees apart, three legs 120 degrees apart, four legs 90 degrees apart, and the like). In some embodiments, each leg 410 may be a portion of a respective RF coil conductor that extends inward to make electrical contact with the first RF feed 402. In some embodiments, the first RF coil 109 may include a plurality of conductors each having a leg 410 that extends inwardly from the coil to couple to the base 408 at respective ones of the symmetrically arranged coupling points (e.g., terminals 428).

The second RF feed 404 may be a conductive tube 403 coaxially disposed about the first RF feed 402. The second RF feed 404 may further include a first end 412 proximate the first and second RF coils 109, 111 and a second end 414 opposite the first end 412. In some embodiments, the second RF coil 111 may be coupled to the second RF feed 404 at the first end 412 via a flange 416, or alternatively, directly to the second RF feed 404 (not shown). The flange 416 may be circular or other in shape and is coaxially disposed about the second RF feed 404. The flange 416 may further include symmetrically arranged coupling points to couple the second RF coil 111 thereto. For example, in FIG. 4A, two terminals 426 are shown disposed on opposite sides of the second RF feed 404 for coupling to two portions of the second RF coil 111 via, for example, screws 427 (although any suitable coupling may be provided, such as described above with respect to terminals 428).

Like the first coil 109, and also discussed further below in relation to FIGS. 5A-B, the second RF coil 111 may comprise a plurality of interlineated and symmetrically arranged stacked coils. Each stacked coil may have a leg 418 extending therefrom for coupling to the flange 416 at a respective one of the symmetrically arranged coupling points. Accordingly, each leg 418 may be symmetrically arranged about the flange 216 and/or the second RF feed 404.

The second end 414 of the second RF feed 404 may be coupled to the match network 119 (as shown), to a power divider (as shown in FIG. 3), or to a phase controller (as shown in FIG. 1). For example, as depicted in FIG. 4A, the match network 119 includes a power divider 430 having two outputs 432, 434. The second end 414 of the second RF feed 404 may be coupled to one of the two outputs of the match network 119 (e.g., 434). The second end 414 of the second RF feed 404 may be coupled to the match network 119 via a conductive element 420 (such as a conductive strap). In some embodiments, the first and second ends 412, 414 of the second RF feed 404 may be separated by a length 422 sufficient to limit the effects of any magnetic field asymmetry that may be caused by the conductive element 420. The required length may depend upon the RF power intended to be used in the process chamber 110, with more power supplied requiring a greater length. In some embodiments, the length 422 may be between about 2 to about 8 inches (about 5 to about 20 cm). In some embodiments, the length is such that a magnetic field formed by flowing RF current through the first and second RF feeds has substantially no effect on the symmetry of an electric field formed by flowing RF current through the first and second RF coils 109, 111.

In some embodiments, and as illustrated in FIG. 4B, an annular disk 424 may be coupled to the second RF feed 404 proximate the second end 414 thereof. The disk 424 may be coaxially disposed about the second RF feed 404. The conductive element 420, or other suitable connector, may be used to couple the disk 424 to the output of the match network (or power divider, or phase controller). The disk 424 may be fabricated from the same kinds of materials as the second RF feed 404 and may be the same or different material as the second RF feed 404. The disk 424 may be an integral part of the second RF feed 404 (as shown), or alternatively may be coupled to the second RF feed 404, by any suitable means that provides a robust electrical connection therebetween, including but not limited to bolting, welding, press fit of a lip or extension of the disk about the second RF feed 404, or the like. The disk 424 advantageously provides an electric shield that lessens or eliminates any magnetic field asymmetry due to the offset outputs from the match network 119 (or from the power divider or phase controller). Accordingly, when a disk 424 is utilized for coupling RF power, the length 422 of the second RF feed 204 may be shorter than when the conductive element 420 is coupled directly to the second RF feed 404. In such embodiments, the length 422 may be between about 1 to about 6 inches (about 2 to about 15 cm).

FIGS. 5A-B depict a schematic top down view of the inductively coupled plasma apparatus 102 in accordance with some embodiments of the present invention. As discussed above, the first and second coils 109, 111 need not be a singular continuous coil, and may each be a plurality (e.g., two or more) of interlineated and symmetrically arranged stacked coil elements. Further, the second RF coil 111 may be coaxially disposed with respect to the first RF coil 111. In some embodiments, the second RF coil 111 is coaxially disposed about the first RF coil 111 as shown in FIGS. 5A-B.

In some embodiments, and illustrated in FIG. 5A, the first coil 109 may include two interlineated and symmetrically arranged stacked first coil elements 502A, 502B and the second coil 111 includes four interlineated and symmetrically arranged stacked second coil elements 508A, 508B, 508C, and 508D. The first coil elements 502A, 502B may further include legs 504A, 504B extending inwardly therefrom and coupled to the first RF feed 402. The legs 504A, 504B are substantially equivalent to the legs 410 discussed above. The legs 504A, 504B are arranged symmetrically about the first RF feed 402 (e.g., they are opposing each other). Typically, RF current may flow from the first RF feed 402 through the legs 502A, 502B into the first coil elements 504A, 504B and ultimately to grounding posts 506A, 506B coupled respectively to the terminal ends of the first coil elements 502A, 502B. To preserve symmetry, for example, such as electric field symmetry in the first and second coils 109, 111, the ground posts 506A, 506B may be disposed about the first RF feed structure 402 in a substantially similar symmetrical orientation as the legs 502A, 502B. For example, and as illustrated in FIG. 5A, the grounding posts 506A, 506B are disposed in-line with the legs 502A, 502B.

Similar to the first coil elements, the second coil elements 508A, 508B, 508C, and 508D may further include legs 510A, 510B, 510C, and 510D extending therefrom and coupled to the second RF feed 204. The legs 510A, 510B, 510C, and 510D are substantially equivalent to the legs 418 discussed above. The legs 510A, 510B, 510C, and 510D are arranged symmetrically about the second RF feed 404. Typically, RF current may flow from the second RF feed 404 through the legs 510A, 510B, 510C, and 510D into the second coil elements 508A, 508B, 508C, and 508D respectively and ultimately to grounding posts 512A, 512B, 512C, and 512D coupled respectively to the terminal ends of the second coil elements 508A, 508B, 508C, and 508D. To preserve symmetry, for example, such as electric field symmetry in the first and second coils 109, 111, the ground posts 512A, 512B, 512C, and 512D may be disposed about the first RF feed structure 402 in a substantially similar symmetrical orientation as the legs 510A, 510B, 510C, and 510D. For example, and as illustrated in FIG. 5A, the grounding posts 512A, 512B, 512C, and 512D are disposed in-line with the legs 510A, 510B, 510C, and 510D, respectively.

In some embodiments, and as illustrated in FIG. 5A, the legs/grounding posts of the first coil 109 may oriented at an angle with respect to the legs/grounding posts of the second coil 111. However, this is merely exemplary and it is contemplated that any symmetrical orientation may be utilized, such as the legs/ground posts of the first coil 109 disposed in-line with the legs/grounding posts of the second coil 111.

In some embodiments, and illustrated in FIG. 5B, the first coil 109 may include four interlineated and symmetrically arranged stacked first coil elements 502A, 502B, 502C, and 502D. Like the first coil elements 502A, 502B, the additional first coil elements 502C, 502D may further include legs 504C, 504D extending therefrom and coupled to the first RF feed 402. The legs 504C, 504D are substantially equivalent to the legs 410 discussed above. The legs 504A, 504B, 504C, and 504D are arranged symmetrically about the first RF feed 402. Like the first coil elements 502A, 502B, the first coil elements 502C, 502D terminate at grounding posts 506C, 506D disposed in-line with legs 504C, 504D. To preserve symmetry, for example, such as electric field symmetry in the first and second coils 109, 111, the ground posts 506A, 506B, 506C, and 506D may be disposed about the first RF feed structure 402 in a substantially similar symmetrical orientation as the legs 502A, 502B, 502C, and 502D. For example, and as illustrated in FIG. 5B, the grounding posts 506A, 506B, 506C, and 506D are disposed in-line with the legs 502A, 502B, 502C, and 502D, respectively. The second coil elements 508A, 508B, 508C, and 508D and all components (e.g., legs/grounding posts) thereof are the same in FIG. 5B as in FIG. 5A and described above.

In some embodiments, and as illustrated in FIG. 5B, the legs/grounding posts of the first coil 109 are oriented at an angle with respect to the legs/grounding posts of the second coil 111. However, this is merely exemplary and it is contemplated that any symmetrical orientation may be utilized, such as the legs/ground posts of the first coil 109 disposed in-line with the legs/grounding posts of the second coil 111.

Although described above using examples of two or four stacked elements in each coil, it is contemplated that any number of coil elements can be utilized with either or both of the first and second coils 109, 111, such as three, six, or any suitable number and arrangement that preserves symmetry about the first and second RF feeds 402, 404. For example, three coil elements may be provided in a coil each rotated 120 degrees with respect to an adjacent coil element.

The embodiments of the first and second coils 109, 111 depicted in FIGS. 5A-B can be utilized with any of the embodiments for altering the phase between the first and second coils as described above. In addition, each of the first coil elements 502 can be wound in an opposite direction to each of the second coil elements 508 such that RF current flowing through the first coil elements is out of phase with RF current flowing through the second coil elements. When a phase controller is used, the first and second coil elements 502, 508 can be wound in the same direction or in an opposite direction.

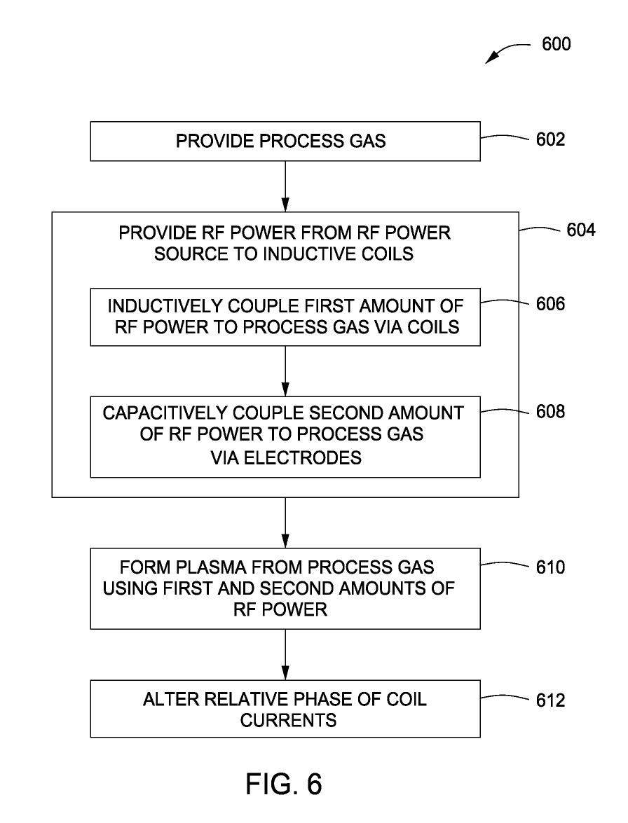

FIG. 6 depicts a method 600 of forming a plasma in a dual mode inductively coupled reactor, similar to the reactor 100 described above, in accordance with some embodiments of the present invention. The method generally begins at 602, where a process gas (or gases) is provided to the process chamber 110. The process gas or gases may be supplied from the gas panel 138 through the entry ports 126 and form the gaseous mixture 150 in the chamber 110. The chamber components, such as the wall 130, the dielectric lid 120, and the support pedestal 116, may be heated to a desired temperature before or after the process gases are provided. The dielectric lid 120 may be heated by supplying power from the power source 123 to the heater element 121. The power supplied may be controlled to maintain the process chamber 110 at a desired temperature during processing.

Next, at 604, RF power from the RF power source 118 may be provided to the plurality of inductive coils and, optionally, to one or more electrodes, to be respectively inductively and, optionally, capacitively coupled to the process gas mixture 150. The RF power may illustratively be provided at up to 4000 W and at a tunable frequency in a range from 50 kHz to 13.56 MHz, although other powers and frequencies may be utilized to form the plasma. In some embodiments, the RF power may be simultaneously provided to both the plurality of inductive coils and the one or more electrodes, where the one or more electrodes are electrically coupled to the inductive coils.

In some embodiments, a first amount of RF power may be inductively coupled to the process gas via the plurality of inductive coils, as shown at 406. In some embodiments, a second amount of RF power may be capacitively coupled to the process gas via one or more electrodes coupled to one of the plurality of inductive coils. The second amount of RF power capacitively coupled to the process gas may be controlled, for example, by increasing (to reduce capacitive coupling) or decreasing (to increase capacitive coupling) the distance between each electrode (e.g., electrodes 112_{A}, 112_{B}) and the dielectric lid 120. As discussed above, the position of the one or more electrodes may be controlled independently such that the electrodes may be equally or unequally spaced from the dielectric lid, The distance between each electrode and the heater element 121 may also be controlled to prevent arcing therebetween.

The second amount of RF power capacitively coupled to the process gas may also be controlled, for example, controlling the tilt, or angle, between the electrode plane (e.g., the bottom of the electrodes 112_{A}, 112_{B}) and the dielectric lid 120. The planar orientation of the one or more electrodes (e.g., electrodes 112_{A}, 112_{B}) may be controlled to facilitate adjusting the second amount of RF power capacitively coupled to the process gas mixture 150 in certain regions of the process chamber 110 (e.g., as the electrode plane is tilted, some portions of the one or more electrodes will be closer to the dielectric lid 120 than other portions).

At 610, the plasma 155 is formed from the process gas mixture 150 using the first and, optionally, second amounts of RF power provided by the inductive coils 109, 111 and the optional electrodes 112_{A-B}, respectively.

At 612, the relative phase of RF current applied to the plurality of coils is adjusted to optimize the process. For example, selecting the phase to be in-phase or out-of-phase (180° shift) may improve the etch rate uniformity across a substrate for a particular process. The relative phase of the RF current applied to the plurality of coils may be adjusted (or selected and set) prior to applying the RF current to the plurality of coils (for example, in anticipation of performing a particular process). In addition, the relative phase of the RF current applied to the plurality of coils may be altered as desired during processing, for example, within a process recipe step, between processing steps, or the like.

Upon striking the plasma, and obtaining plasma stabilization, the method 600 continues plasma processing as desired. For example, the process may continue, at least in part, using the RF power settings and other processing parameters per a standard process recipe. Alternatively or in combination, the one or more electrodes may be moved further away from the dielectric lid 120 to reduce the capacitive coupling of RF power into the process chamber 110 during the process. Alternatively or in combination, the one or more electrodes may be moved closer to the dielectric lid 120, or may be tilted at an angle to increase the capacitive coupling of RF power into the process chamber 110 or to control the relative quantity of RF power capacitively coupled into regions of the process chamber 110. In addition, coil current phase control may be used to further control process optimization.

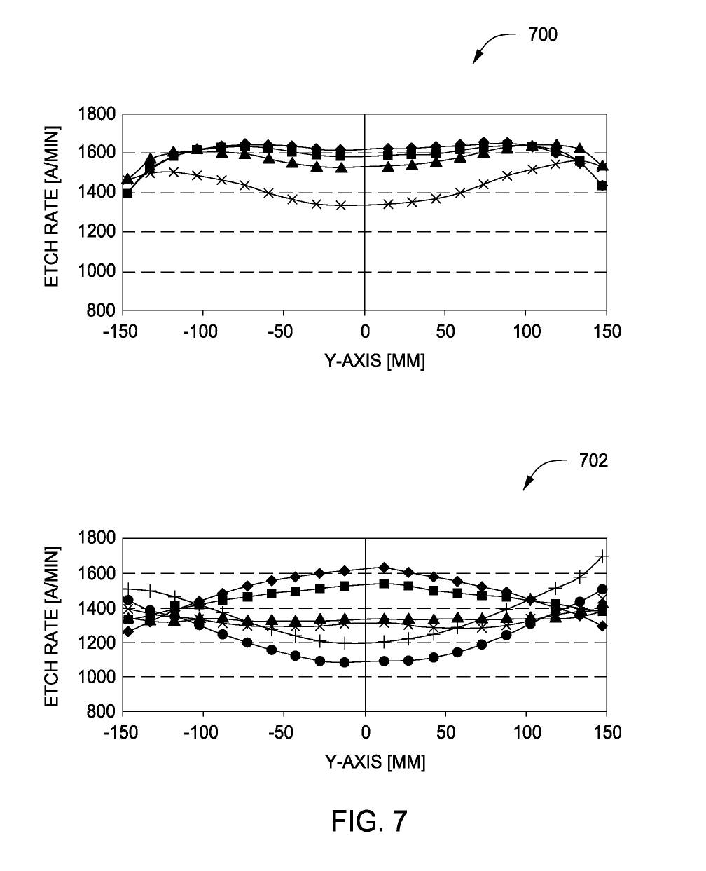

FIG. 7 depicts an illustration comparing a typical etch rate profile graph 700 and an etch rate profile graph 702 achieved using a 180 degree out-of-phase coil current. Note that the etch rate profiles in graph 700 has an M-shape, while, in response to a change in current phase, profiles in graph 702 has a flatter profile. More specifically, profile graph 700 comprises a plurality of profiles, each representing an etch rate across a wafer at a specific current ratio between the coils, while the currents are in-phase. Note the distinct M-shaped profile at various current ratios having a lower etch rate near the edge of the wafer and at the middle. In contrast, profile graph 702 illustrates a plurality of profiles that occur at various current ratios when the current to each coil is out of phase (e.g., a negative current ratio). Note the profiles are no longer M-shaped and adjustment of the current ratio can achieve substantially varied profiles. Consequently, controlling both phase and current ratio during a process can provide substantially improved process control.

Thus, a dual mode inductively coupled plasma reactor and methods of use have been provided herein. The dual mode inductively coupled plasma reactor of the present invention may advantageously improve etch rate uniformity by selectively applying coil current phase changes. The dual mode integrated plasma reactor of the present invention may further advantageously control, and/or adjust, plasma characteristics such as uniformity and/or density during processing.

While the foregoing is directed to embodiments of the present invention, other and further embodiments of the invention may be devised without departing from the basic scope thereof.

1. A dual mode inductively coupled plasma processing system, comprising:
a process chamber having a dielectric lid; and
a plasma source assembly disposed above the dielectric lid, the plasma source assembly comprising:
a plurality of coils configured to inductively couple RF energy into the process chamber to form and maintain a plasma therein;
a phase controller coupled to the plurality of coils for controlling the relative phase of RF current applied to each coil in the plurality of coils; and
an RF generator coupled to the phase controller.

2. The system of claim 1, wherein the plurality of coils further comprise:
an outer coil; and
an inner coil.

3. The system of claim 1, wherein the plasma source assembly comprises one or more electrodes configured to capacitively couple RF energy into the process chamber to form the plasma therein, wherein the one or more electrodes are electrically coupled to one of the one or more coils.

4. The system of claim 3, wherein the one or more electrodes further comprise:
two electrodes equidistantly spaced apart and disposed between the inner coil and the outer coil, wherein each electrode is electrically coupled to the outer coil.

5. The system of claim 1, wherein the phase controller further comprises:
a capacitive divider having a fixed capacitor and a variable capacitor.

6. The system of claim 5, wherein the plurality of coils are connected in series, wherein the plurality of coils comprise an inner coil wound in a first direction and an outer coil wound in a second direction, where the first and second directions are opposite each other.

7. The system of claim 1, further comprising:
a heater element disposed between the dielectric lid and the one or more electrodes of the plasma source assembly.

8. The system of claim 1, wherein the phase controller selectively supplies in-phase RF current and 180 degree out-of-phase RF current to the plurality of coils.

9. The system of claim 1, further comprising:
a support pedestal disposed within the process chamber having a bias power source coupled thereto.

10. The system of claim 1, wherein the phase controller further comprises:
a power divider disposed between the RF generator and the plurality of coils; and
a capacitor coupled between one of the plurality of coils and ground.

11. The system of claim 10, wherein the plurality of coils are connected in parallel.

12. A method of forming and using a plasma, comprising:
providing a process gas to an inner volume of a process chamber having a dielectric lid and having a plurality of coils disposed above the lid;
providing RF power to the plurality of coils from an RF power source;
forming a plasma from the process gas using the RF power provided by the RF power source that is inductively to the process gas by the plurality of coils; and
adjusting the relative phase of RF current applied to each coil in the plurality of coils.

13. The method of claim 12, wherein:
the plurality of coils comprises two coils and the adjusting selectively supplies RF current in-phase to each of the coils or 180 degrees out-of-phase to each of the coils; or
the adjusting further comprises altering at least one capacitance value of a capacitor in a capacitive divider that splits RF current amongst the plurality of coils.

14. The method of claim 12, further comprising providing RF power to at least one electrode coupled to at least one of the plurality of coils.

15. The method of claim 12, wherein the process chamber further comprises a heater element disposed atop the lid, and further comprising:
supplying power to the heater element from a AC power supply to control a temperature of the process chamber.

16. A dual mode inductively coupled plasma processing system, comprising:
a process chamber having a dielectric lid;
an annular heater positioned proximate the dielectric lid;
a plasma source assembly disposed above the dielectric lid, the plasma source assembly comprising:
a first coil being would in a first direction and a second coil being would in a second direction, the first and second coils configured to inductively couple RF energy into the process chamber to form and maintain a plasma therein;
a phase controller coupled to the first and second coils for controlling the relative phase of RF current applied to each coil;
one or more electrodes configured to capacitively couple RF energy into the process chamber to form the plasma therein, wherein the one or more electrodes are electrically coupled to one of the one or more coils; and
an RF generator coupled to the phase controller and each of the coils through a central feed.

17. The system of claim 16, wherein the first direction and second direction are opposite one another.

18. The system of claim 16, wherein the first coil and the second coil are coupled in series with a blocking capacitor to ground coupled between the first coil and the second coil.

19. The system of claim 18, wherein the one or more electrodes are formed by connectors coupling the first coil and the second coil.

20. The system of claim 18, further comprising:
a match network coupled between the RF generator and the first and second coils, the match network having a dividing capacitor, wherein the dividing capacitor and the blocking capacitor together comprise the phase controller, wherein the phase controller controls the current ratio in addition to the relative phase of the RF current flowing through the first and second coils.
